(19) United States
(12) Patent Application Publication
(10) Pub. No.: US 2011/0034336 A1
(43) Pub. Date: Feb. 10, 2011

(54) CRITICAL CURRENT DENSITY ENHANCEMENT VIA INCORPORATION OF NANOSCALE Ba2(Y,RE)NbO6 IN REBCO FILMS

(76) Inventors: Amit Goyal, Knoxville, TN (US); Sung-Hun Wee, Knoxville, TN (US); Eliot Specht, Knoxville, TN (US); Claudia Cantoni, Knoxville, TN (US)

Correspondence Address: NOVAK DRUCE +QUIGG LLP/UTB, CITY PLACE TOWER, 525 OKEECHOBEE BLVD., 15TH FLR, WEST PALM BEACH, FL, 33401, US

(21) Appl. No.: 12/850,398

(22) Filed: Aug. 4, 2010

Related U.S. Application Data
(60) Provisional application No. 61/231,187, filed on Aug. 4, 2009.

(51) Int. Cl. H01L 39/12; H01L 39/24; B32B 7/00; B05D 5/12; C23C 14/34; C23C 14/00; H01L 41/187

(52) U.S. Cl. 505/100; 505/150; 505/470; 505/474; 505/473; 505/475; 428/148; 428/119; 427/63; 204/192.11; 204/192.18; 252/62.9 R

(57) ABSTRACT

A superconducting article includes a substrate having a biaxially textured surface, and an epitaxial biaxially textured superconducting film supported by the substrate. The epitaxial superconducting film includes particles of Ba₂RENbO₆ and is characterized by a critical current density higher than 1 MA/cm² at 77K, self-field. In one embodiment the particles are assembled into columns. The particles and nanocolumns of Ba₂RENbO₆ defects enhance flux pinning which results in improved critical current densities of the superconducting films. Methods of making superconducting films with Ba₂RENbO₆ defects are also disclosed.

### CROSS-REFERENCE TO RELATED APPLICATIONS

This Application claims priority to U.S. Provisional Patent Application No. 61/231,187, entitled “Critical Current Density Enhancement via Incorporation of Nanoscale Ba₂(Y,RE)NBO₆ in REBCO Films,” filed Aug. 4, 2009, the entirety of which is incorporated herein by reference.

### STATEMENT REGARDING FEDERALLY SPONSORED RESEARCH OR DEVELOPMENT

The United States Government has rights in this invention pursuant to Contract No. DE-AC05-00OR22725 between the United States Department of Energy and UT-Battelle, LLC.

### FIELD OF THE INVENTION

This invention relates to superconducting materials and more particularly to the pinning enhancement of superconducting materials.

### BACKGROUND OF THE INVENTION

Methods for the preparation of films of high temperature superconductor (FITS) materials on various substrates are well known. These methods have been instrumental for converting HTS materials into tapes and wires, a necessary step in the effort for integrating these materials as wiring into conventional electrical grid systems and devices. Several companies produce HTS wires and tapes of various lengths.

The first HTS tapes suffered from unacceptably low critical current densities, a problem caused by poor alignment of grains in the HTS film or coating with grains of the substrate. Several techniques have therefore been developed to fabricate wires or tapes wherein grain alignment is produced. Of particular note is epitaxial growth of superconductors on such ordered substrates as the Rolling-Assisted-Biaxially-Textured-Substrates (RABiTS). RABiTS substrates typically include a textured metal underlayer (for example, nickel or nickel alloy) and an epitaxial buffer layer (for example, Y₂O₃ and/or yttria-stabilized zirconia, YSZ, and/or cerium oxide, CeO₂). Epitaxial superconductors on biaxially-textured substrates have significantly improved critical current densities of HTS tapes, and thus, improved suitability for commercial applications.

A problem of HTS tapes and wires is the dissipation in critical current density (typically expressed as J_{c}) of the superconductor film when the superconductor film is exposed to an external magnetic field. Since external magnetic fields (typically as high as 5 Tesla, or higher) are prevalent in most commercial and industrial applications, there has been a significant effort to incorporate design features into the superconductor film that mitigate these current density losses. One particularly promising method has been to introduce structural defects (i pinning defects) into the superconductor film. The pinning defects have been found to significantly reduce current density losses in superconductor films in the presence of an external magnetic field.

Flux pinning is the phenomenon that magnetic flux lines do not move (or are “pinned”) in spite of the Lorentz force acting on them inside a current-carrying Type II superconductor. Flux pinning is desirable in high-temperature ceramic superconductors to prevent “flux creep”, which can create a pseudo-resistance and depress both critical current density and critical field. Degradation of a high-temperature superconductor's properties due to flux creep is a limiting factor in the use of these superconductors. In order to realize the full potential of high temperature superconducting wires (HTS coated conductors) for various commercial electric-power equipment, the flux pinning properties of REBa₂Cu₃O₇ films (REBCO, RE=Y or a rare earth element) need to be improved in a controlled, reproducible and practical fashion. Improvements in pinning efficiency not only enhance the critical current density (J_{c}) under high magnetic fields (B), but also may help reduce the field dependent anisotropy in (J_{c}), for in-field orientations ranging from the ab-plane to the c-axis. The latter advancement is especially important for such power utility applications as motors, generators, and transmission lines, where FITS cables experience-varying magnetic field strengths and directions.

Flux pinning is only possible when there are defects in the crystalline structure of the superconductor (usually resulting from grain boundaries or impurities). Physical methods such as laser scribing or photolithographic patterning have been utilized to introduce pinning defects into the superconductor film. Recent research has also been conducted on introducing such defects into superconducting films by growing superconducting films epitaxially on substrates possessing microstructural defects.

In recent years, the issue of improving the effective pinning of magnetic flux lines in FITS films has been successfully addressed by many groups through manipulation of defects in REBCO film matrix. That is, through various methods additional pinning centers of different sizes and morphologies, in addition to the existing naturally formed growth-induced defects, have been introduced into REBCO films. One particularly successful and heavily studied dopant is BaZrO₃ (BZO), first incorporated into the YBCO films, in the form of 5-100 nm size particles, by pulsed laser deposition (PLD). This was followed by the demonstration of strain-induced formation of columnar defects, comprising self-assembled nanodots and/or nanorods of BZO within the superconducting matrix. Similar columnar defects were also observed by incorporation of yttria-stabilized zirconia (YSZ) in REBCO films. Enhanced flux pinning through Zr additions by MOCVD has been described in Enhanced flux pinning by BaZrO3 and (Gd, Y)2O3 nano-structures in metal organic chemical vapor deposited GdYBCO high temperature superconductor tapes,” Y Chen, V. Selvamanickam, Y Zhang, Y L. Zuev, C. Cantoni, E. D. Specht, M. P. Paranthaman, T Aytug, A. Goyal and D. Lee, Appl. Phys. Lett., vol. 94, Article Number: 062513, 2009 and Enhanced flux pinning in MOCVD-YBCO films through Zr additions: systematic feasibility studies; Aytug et al, Supercond. Sci. Technol. 23 (2010) 014005. The use of MOCVD to deposit YBCO films is described in Deposition studies and coordinated characterization of MOCVD YBCO films on IBAD-MgO templates; Aytug et al., Supercond. Sci. Technol. 22 (2009) 015008, Incorporation of nanodots and nanorods into superconducting articles and other devices is also described in Patent Application Publications Goyal US 2008/0176749 (Jul. 24, 2008) and Goyal et al US 2009/0088325 (Apr. 2, 2009). The disclosure of these references is hereby incorporated fully by reference. The columnar defects have proven to be very effective for enhancing the pinning performance, especially for fields applied near the c-axis of the REBCO film.

### SUMMARY OF THE INVENTION

An article comprising a substrate having a biaxially textured surface, and an epitaxial biaxially textured superconducting film supported by the substrate is disclosed. The epitaxial superconducting film comprises nanoparticles of double perovskite, Ba₂RENbO₆ and is characterized by a critical current density higher than 1 MA/cm² at 77K, self-field.

The substrate can be selected from the group comprising a single-crystal substrate, a RABiTS substrate, and an IBAD substrate. The particles of Ba₂RENbO₆ can be in the form of aligned columns, aligned within 20 degrees from the c-axis of the superconducting film. The columns can be comprised of particles. The columns can also be comprised of nanorods. The superconducting film can be characterized by an I_{c} greater than 300 A/cm at 65K, 3 T.

A method of making a superconducting article comprising a biaxially textured superconducting material and characterized by a critical current density higher than 1 MA/cm² at 77K, self-field, can include the steps of (a) providing a buffered biaxially textured or single crystal substrate and (b) performing simultaneous deposition of the biaxially textured superconducting material and nanoparticles of double perovskite Ba₂RENbO₆.

The deposition step can include an in-situ deposition process selected from the group consisting of pulsed laser ablation, chemical vapor deposition (CVD), metallorganic chemical vapor deposition (MOCVD), sputtering and e-beam co-evaporation. The deposition step can include an ex-situ deposition process selected from the group consisting of chemical solution processes, and an ex-situ BaF₂ process, followed by a heat treatment. The chemical solution process can be selected from the group consisting of TFA-MOD, non-fluorine MOD processes, and reduced fluorine MOD processes.

A method of making a superconducting film comprising a biaxially textured superconducting material and characterized by a critical current density higher than 1 MA/cm² at 77K, self-field, can include the steps of (a) providing a buffered biaxially textured or single crystal substrate (b) heating the substrate to a preselected deposition temperature under a preselected gas atmosphere and pressure (c) performing simultaneous deposition of the biaxially textured superconducting material and nanoparticles of double perovskite Ba₂RENbO₆.

The simultaneous deposition can be done using an in-situ deposition process selected from the group consisting of pulsed laser ablation, chemical vapor deposition (CVD), metallorganic chemical vapor deposition (MOCVD), sputtering and e-beam co-evaporation. The simultaneous deposition can be done using an ex-situ deposition process selected from the group consisting of chemical solution processes, and an ex-situ BaF₂ process, followed by a heat treatment. The chemical solution process can be selected from the group consisting of TFA-MOD, non-fluorine MOD processes, and reduced fluorine MOD processes.

A superconducting article can comprise a biaxially textured superconducting composition containing RE, Ba, Cu and O and nanoparticles of double perovskite, Ba₂(Y,RE)NbO₆ and being characterized by a critical current density higher than 1 MA/cm² at 77K, self-field. The superconducting composition can comprise REBCO.

The particles of Ba₂RENbO₆ can be in the form of aligned columns, aligned within 20 degrees from the c-axis of the superconducting film. The columns can be comprised of particles. The columns can be comprised of nanorods. The superconducting film can be characterized by an I_{c} greater than 300 A/cm at 65K, 3 T.

### BRIEF DESCRIPTION OF THE DRAWINGS

A fuller understanding of the present invention and the features and benefits thereof will be obtained upon review of the following detailed description together with the accompanying drawings, in which:

FIG. 1A is a schematic diagram illustrating the crystal structure of the double niobate phase—Ba₂RENbO₆. FIG. 1B is a plot of reduced lattice parameter (A) and lattice mismatch with YBCO (%) vs. ionic radius of RE³⁺ for several compounds including Ba₂RENbO₆, RE₃TaO₇, and RE₂O₃.

FIG. 2 shows x-ray diffraction results illustrating the inertness of the Ba₂RENbO₆ phase with YBCO phase.

FIG. 3 shows X-ray diffraction results for YBCO films containing Ba₂YNbO₆ nanophase. (A) shows θ-2θ scans for YBCO films with different % volume fractions of Ba₂YNbO₆ nanophase from 0 to 5.1%. (B) shows omega (ω) and phi (φ) scans of YBCO and Ba₂YNbO₆ phases taken from 5.1% Ba₂YNbO₆ doped YBCO film.

FIG. 4 shows transmission electron micrographs of ˜0.5-μm-thick YBCO film with 5.1% Ba₂YNbO₆ nanophase on IBAD-MgO templates. (A) Cross-section TEM image showing the presence of columnar defects comprised of self-assembled Ba₂YNbO₆ nanodots in general along the c-axis as indicated by arrows. (B) A higher magnification image showing a Ba₂YNbO₆ column comprised of a stack of nanorods. (C) Selected area diffraction (SAD) patterns taken from a cross-section TEM specimen indicating the presence of cubic, double perovskite Ba₂YNbO₆ nanocolumns.

FIG. 5 shows the field dependent J_{c} at 77 K, H∥c with the magnetic field up to 8 T (A) and the angular dependent J_{c}, at 77 K, 1 T (B) for un-doped. YBCO films, 1.3% doped YBCO films, and 5.1% doped YBCO films.

### DETAILED DESCRIPTION OF THE INVENTION

The present invention incorporates a Ba₂(Y, RE)NbO₆ phase into particles or substantially aligned columns within a superconducting film. Since the Ba₂(Y, RE)NbO₆ phase has a large lattice mismatch with superconducting films, such as REBCO or YBCO films, significant strain is generated by the presence of this phase. Self-aligned or randomly distributed particles of Ba₂(Y, RE)NbO₆ can cause significant improvements in flux pinning, which can result in significant enhancement in the critical current density (J_{c}) of the superconducting film. Also, the strain caused by the lattice mismatch can cause vertical self-assembly of particles of Ba₂(Y, RE)NbO₆ into columns. The particles can also merge to form nanorods. The columns also cause significant improvements in flux pinning, with resulting improvements in J_{c}.

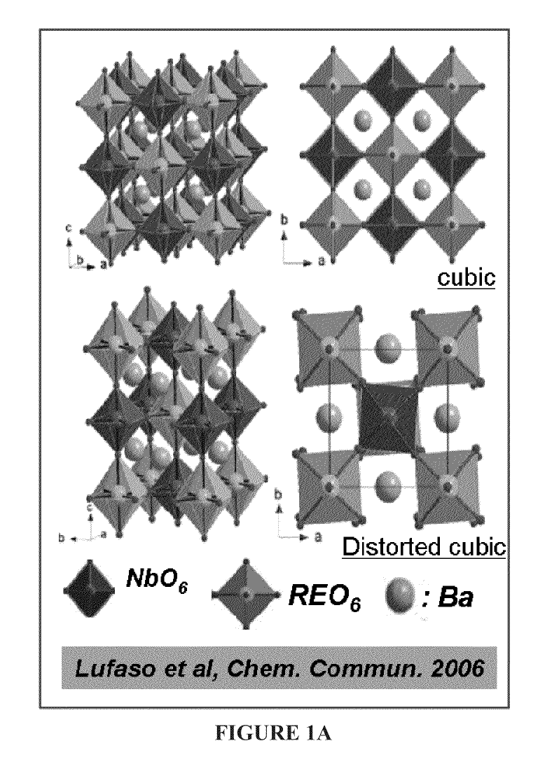

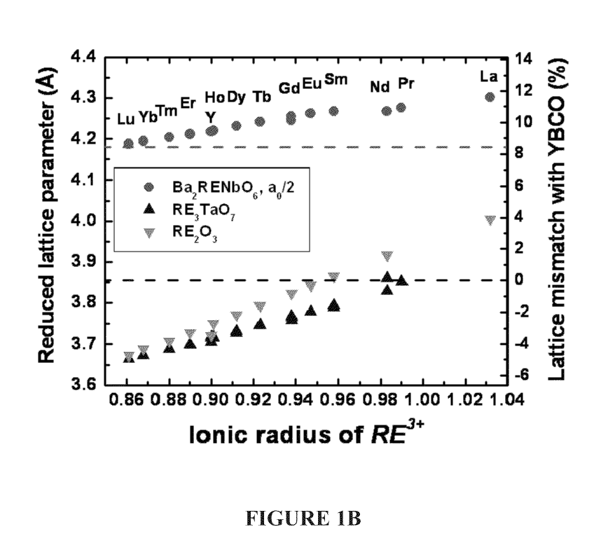

The structure of the Ba₂(Y,RE)NbO₆ phase in the superconducting film is a double perovskite niobate. FIG. 1A shows the crystal structure of this double perovskite niobate phase. This phase has a large lattice mismatch with YBCO. FIG. 1B is a plot of the lattice mismatch of this phase with YBCO, as well as some other phases such as BaZrO₃, RE₂O₃, and RE₃TaO₇. The plot shows that the lattice mismatch of the double perovskite phase, Ba₂RENbO₆, is higher than that of BZO, in the range of 8-12%, which is ideal to create enough strain for the self-assembly of columnar defects comprising aligned particles of Ba₂(Y, RE)NbO₆. Ba₂(Y, RE)NbO₆ accordingly is an excellent candidate for forming self-assembled columnar defects in REBCO films.

The particles and columns of the Ba₂(Y, RE)NbO₆ defects in the superconducting film can be substantially evenly/homogeneously distributed throughout the superconducting film. The concentration of the defects in the superconducting material can vary. In one aspect, the number density of defects can be between 400 and 4×10⁴ μm⁻² corresponding to interspacing distance between particles or columns in the range of 5 to 50 nm in the superconducting film.

The thickness (e.g., width or largest dimension) of the Ba₂(Y, RE)NbO₆ features in the superconducting film is generally of nanoscale dimension, i.e., less than 1 μm thick. For example, in different embodiments, the largest dimension of the features can be less than 500 nm, or less than 200 nm, or less than 100, 90, 80, 70, 60, 50, 40, 30, 20, or less than 10 nm. The smallest dimension of the particle or column features can be greater than 1, 2, 3, 4, 5, 10, 20, 30, 40 or 50 nm. The particles or columns can also have any combination of the aforesaid largest dimensions and smallest dimensions. However, smaller or larger thicknesses of the columnar features are also possible. More typically, the largest dimension of the nanoscale defects is in the range of 1-100 nm. The diameter of the particles can be between 1 nm and 100 nm. The diameter of the particles will depend on the type of processes and processing conditions. In the case of columnar features, the length of the columns will be up to the entire film thickness of REBCO superconducting layer. The length will depend on the type of processes and processing conditions. The width of the columns will be between 1 nm and 100 nm. The width of the columns will depend on the type of processes and processing conditions.

The self-assembled defects are generally disposed linearly, for example, as columns, in the superconducting film in an orientation generally perpendicular to the superconducting film surface (c-axis), or parallel to the direction of film growth. It is also possible that conditions can be employed that could provide for the creation of non-linear (for example, curved or bent) defects in the superconducting film. Furthermore, it is contemplated that conditions can be employed that could provide for linearly or non-linearly propagated defects to depart from a perpendicular orientation to the surface, for example, within +1/−1 degrees to within +90/−90 degrees of the perpendicular, or any angular orientation there between. In one embodiment, the defects are aligned within +201-20 degrees of the c-axis of the superconducting film.

Superconducting films according to the invention are characterized by a critical current density (J_{c}) higher than 1 MA/cm² at 77K, self-field. Superconducting films according to the invention can also be characterized by an critical current (I_{c}) greater than 300 A/cm at 65K, 3 T.

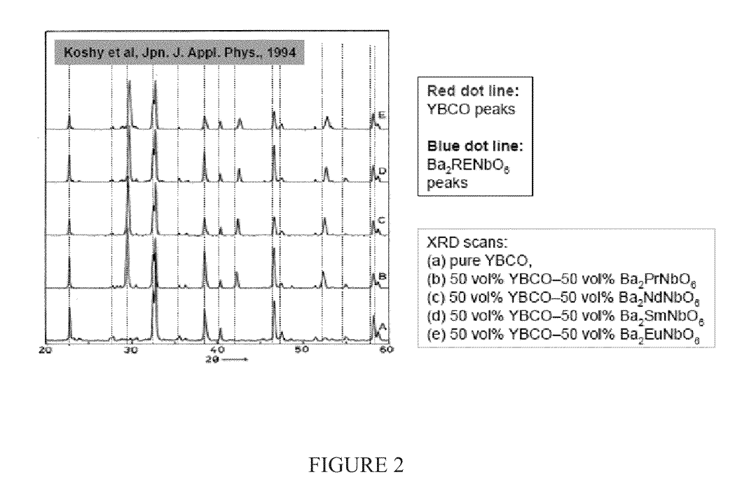

The primary phase of the superconducting film can be one of many high temperature superconductor (HTS) materials known in the art. A high temperature superconducting material is generally characterized by having a superconducting critical temperature (T_{c}) of at least 35 K, and more preferably, greater than 77 K. Currently, a majority of the HTS materials belong to the general class of copper oxide superconducting materials. The HTS material also should be substantially chemically inert with Ba₂(Y, RE)NbO₆. FIG. 2 shows x-ray diffraction results from prior work showing the inertness of the Ba₂(Y, RE)NbO₆ phase with YBCO superconductor [Koshy et al, Jpn. J. Appl. Phys., 1994, incorporated by reference].

In one embodiment, the superconducting film includes a rare-earth (RE) or transition metal barium copper oxide composition (hereinafter, a “metal-barium-copper-oxide” or “REBCO” composition). The rare earth element can be any of the lanthanide or actinide metals listed in the Periodic Table of the Elements (hereinafter, the “Periodic Table”). The lanthanide metals refer predominantly to the elements of the Periodic Table having an atomic number of 57 to 71. The actinide metals generally refer to any of the elements of the Periodic Table having an atomic number of 90 to 103. In a particular embodiment, the metal-barium-copper-oxide material is according to the formula (RE)Ba₂Cu₃O₇, wherein RE is a rare earth or transition metal element. Some examples of suitable RE metals include, yttrium (Y), neodymium (Nd), gadolinium (Gd), thulium (Tm), ytterbium (Yb), lutetium (Lu), and combinations thereof. The transition metals generally refer to any of the elements located in Groups 3-12 of the Periodic Table (i.e., the corresponding scandium through zinc groups). In still another embodiment, the HTS film includes a lanthanum-containing copper oxide material. The lanthanum-containing copper oxide material can include a composition according to the general formula La₂₋ₓMₓCuO₄, wherein x is greater than zero and less than 2, and M is an alkaline earth metal ion, such as Mg, Ca, Sr, or Ba. Some specific examples of such superconducting materials include La_{1.85}Ba_{0.15}CuO₄(LBCO) and La_{1.85}Sr_{0.15}Cua₄(LSCO).

Other metal barium copper oxide compositions can also be suitable. For example, in one embodiment, the superconducting material is an yttrium barium copper oxide (YBCO) material. Any of the yttrium barium copper oxide superconducting materials known in the art can be used herein. In one instance, the yttrium barium copper oxide material can be generally described by the formula YBa₂Cu₃O₇₋ₓ, wherein x is generally a number within the approximate range 0≦x≦1. As used herein, the formula YBa₂Cu₃O₇ is ascribed the same meaning, and includes all of the possible different variations, as encompassed by the former broader formula. Some examples of other types of yttrium barium copper oxide materials include Y₃Ba₄Cu₇O₁₆, Y₂Ba₄Cu₇O₁₅, Y₂CaBa₄Cu₇O₁₆, (Y_{0.5}Lu_{0.5})Ba₂Cu₃O₇, (Y_{0.5}Tm_{0.5})Ba₂Cu₃O₇, and (Y_{0.5}Gd_{0.5})Ba₂Cu₃O₇.

In another embodiment, the high temperature superconducting film includes a thallium-containing barium copper oxide composition. More particularly, the composition may be a thallium barium calcium copper oxide material. Any of the thallium barium calcium copper oxide materials can be used herein. In one instance, the thallium barium calcium copper oxide material includes a composition according to the formula TlBa₂Caₙ₋₁CuₙO₂ₙ₊₃, wherein n is generally a number greater than 1 and up to 4. In another instance, the thallium barium calcium copper oxide material includes a composition according to any of the formulas Tl₂Ba₂Caₙ₋₁CuₙO₂ₙ₊₂, Tl₂Ba₂Caₙ₋₁CuₙO₂ₙ₊₃ or Tl₂Ba₂Caₙ₋₁CuₙO₂ₙ₊₄, wherein n is generally a number greater than 1 and up to 4. Some specific examples of such superconducting compositions include Tl₂Ba₂Ca₂Cu₃O₁₀ (TBCCO-2223), Tl₂Ba₂CaCu₂O₆, TlBa₂Ca₂Cu₃O₉, and TlBa₂Ca₃Cu₄O₁₁.

In another embodiment, the high temperature superconducting film includes a mercury-containing barium copper oxide material. More particularly, the composition may be a mercury barium calcium copper oxide material. Any of the mercury barium calcium copper oxide materials can be used herein. In a particular embodiment, the mercury barium calcium copper oxide material includes a composition according to the formula HgBa₂Caₙ₋₁CuₙO_{2n+2, wherein n is a number greater than} 1 and up to 4. Some specific examples of such superconducting compositions include HgBa₂Ca₂Cu₃O₈, HgBa₂Ca₂Cu₄O₁₀, HgBa₂(Ca₁₋ₐSrₐ)Cu₃O₈ (wherein 0≦a≦1), and (Hg_{0.8}Tl_{0.2})Ba₂Ca₂Cu₃O_{8+x.}

In yet another embodiment, the high temperature superconducting film includes a bismuth- and/or strontium-containing calcium copper oxide material. More particularly, the composition may be a bismuth strontium calcium copper oxide (BSCCO) material. Any of the BSCCO materials can be used herein. In a particular embodiment, the BSCCO material includes a composition according to the formula Bi₂Sr₂CaₙCuₙ₊₁O₂ₙ₊₆. Some specific examples of such superconducting compositions include Bi₂Sr₂CaCu₂O₈ (BSCCO-2212) Bi₂Sr₂Ca₂Cu₃O₁₀ (BSCCO-2223), Bi₂Sr₂CaCu₂O₉, and Bi₂Sr₂(Ca_{0.8}Y_{0.2})Cu₂O₈.

Any of the superconducting materials described above can include dopant amounts of other metals that may be included to facilitate certain desired properties of the HTS film. Some examples of rare earth dopants include yttrium (Y), lanthanum (La), cerium (CO, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), or a combination thereof. In a particular embodiment, YBCO film compositions are doped with one or more of the above rare earth metals.

The superconducting film can also be composed of one or more than superconducting layer(s). For example, it may be preferred in certain embodiments to apply a YBCO layer onto a BSCCO layer, or vice-versa.

The superconducting film can be of any suitable thickness. For electrical power applications, the thickness is typically no more than about 5 microns (5 μm) thick, and more typically no more than about 10 μm thick. For example, in different embodiments, the thickness of the superconducting film can be about 5, 4, 3, 2, or 1 μm. However, the thickness is highly dependent on the particular application, and thus, can be of significantly greater thickness (e.g., 10, 15, 20, 25 or more microns), or alternatively, of much lesser thickness (e.g., no more than 1, 0.5, 0.2, or 0.1 microns).

The superconducting films can be formed by many different processes, including in-situ processes and ex-situ processes. In-situ processes include pulsed laser ablation, MOCVD, sputtering or e-beam co evaporation, chemical vapor deposition (CVD), and metallorganic chemical vapor deposition (MOCVD).

Ex-situ processes include chemical solution processes such as metal organic deposition using trifluoroacetates precursor solution (TFA-MOD), non-fluorine MOD processes, and reduced fluorine MOD processes, and the ex-situ BaF₂ process wherein a precursor film is first deposited, followed by a heat treatment to epitaxially form the film.

The superconducting layer can also be coated with any of a variety of materials that can serve a useful purpose. For example, a non-superconducting metal layer may be applied on the superconducting film to protect the film, such as for corrosion resistance. Alternatively, a coating (e.g., metallic, polymeric, plastic, rubber, paint, or hybrid) can be applied onto the superconducting layer to provide, for example, electrical or magnetic insulation, or a certain level of rigidity or flexibility.

The superconducting film can be supported on or deposited on any of several suitable substrates known in the art. The primary substrate considered herein possesses an ordered (i.e., typically, biaxially-textured) surface upon which the phase-separated layer is deposited. For example, any of the biaxially-textured substrates known in the art can be used as the primary substrate on which the phase-separated layer is deposited. As used herein, “supported on” refers to a layer that is above another layer, while “deposited on” refers to a layer that is above and in physical contact with another layer.

The term “biaxially-textured substrate” as used herein is meant to be synonymous with the related term “sharply biaxially-textured substrate.” By one definition, a biaxially-textured substrate is a polycrystalline substrate wherein the grains are aligned within a specific angular range with respect to one another, as would generally be found on the surface of a bulk single crystal. A polycrystalline material having biaxial texture of sufficient quality for electromagnetic applications can be generally defined as having an x-ray diffraction phi scan peak of no more than 20° full-width-half-maximum (FWHM) and an omega-scan of 10° FWHM. The X-ray phi-scan and omega-scan measure the degree of in-plane and out-of-plane texture, respectively. An example of biaxial texture is the cube texture with orientation {100}<100>, wherein the (100) crystallographic plane of all grains is parallel to the substrate surface and the crystallographic direction is aligned along the substrate length.

Other suitable definitions can also be used for defining a biaxially-textured substrate. For example, a biaxially-textured substrate can be defined as a substrate having a crystallographic orientation such that the substrate possesses a FWHM within 7°, preferably within 5°, and more preferably within 3° throughout the crystal. Furthermore, the biaxially-textured substrate need not be polycrystalline (i.e., multi-grained), but may be single-crystalline (i.e., single-grained).

Several types of biaxially-textured substrates are known, all of which are suitable for the purposes herein. Among them, a class of primary substrates suitable for use herein is the class of rolling assisted, biaxially-textured substrates (RABiTS). The RABiTS method produces a polycrystalline substrate having primarily low angle grain boundaries. Further details of the RABiTS technique and formed substrates can be found in, for example, A. Goyal, et al., J. of Materials Research, vol. 12, pgs. 2924-2940, 1997, and D. Dimos et al., Phys. Rev. B, 41:4038-4049, 1990, the disclosures of which are incorporated herein by reference.

The RABiTS technique provides a simple method for fabricating long lengths of biaxially-textured substrates with primarily low-angle grain boundaries. These substrates have been widely employed for the epitaxial deposition of high temperature superconducting (FITS) materials. A number of U.S. patents directed to the RABiTS process and related process variants have been issued. These include U.S. Pat. Nos. 5,739,086; 5,741,377; 5,846,912; 5,898,020; 5,964,966; 5,958,599; 5,968,877; 6,077,344; 6,106,615; 6,114,287; 6,150,034; 6,156,376; 6,151,610; 6,159,610; 6,180,570; 6,235,402; 6,261,704; 6,270,908; 6,331,199; 6,375,768, 6,399,154; 6,451,450; 6,447,714; 6,440,211; 6,468,591, 6,486,100; 6,599,346; 6,602,313, 6,607,313; 6,607,838; 6,607,839; 6,610,413; 6,610,414; 6,635,097; 6,645,313; 6,537,689, 6,663,976; 6,670,308; 6,675,229; 6,716,795; 6,740,421; 6,764,770; 6,784,139; 6,790,253; 6,797,030; 6,846,344; 6,782,988; 6,890,369; 6,902,600; and 7,087,113, the disclosures of which are incorporated herein by reference in their entireties.

In a preferred embodiment, a RABiTS substrate is prepared generally as follows. Briefly, a deformed metal substrate with a very well-developed copper-type (Cu-type) rolling texture is first provided. The metal can be any suitable metal, and typically a FCC type of metal (e.g., Cu, Co, Mo, Cd, Pd, Pt, Ag, Al, Ni, and their alloys), and more preferably, nickel and its alloys (e.g., NiW). A substrate with a Cu-type rolling texture can be readily identified, as known in the art, and as disclosed in, for example, U.S. Pat. No. 7,087,113. For example, a Cu-type rolling texture generally exhibits the characteristic that the X-ray intensity in the pole figures is concentrated on the β-fiber in Euler space of orientation representation. In other words, a Cu-type rolling texture is generally characterized by an orientation of all the grains in the material lying on the β-fiber. The β-fiber is defined as the tube or fiber running from the B through the S to the C point in Euler space. Cu-type rolling texture is generally best shown using pole figures of (111), (200), and (220) from the substrate or drawing the orientations in Euler Space. Next, the metal with Cu-type rolling texture is annealed at a temperature higher than its secondary recrystallization temperature to provide exaggerated grain growth such that a single grain consumes other grains to form an essentially single crystalline (i.e., single grain) type of material (hereinafter, a “single crystal substrate”).

Typically, at least one buffer layer is epitaxially deposited on the surface of the single crystal substrate. The function of the buffer layer is typically as a chemical barrier between the single crystal substrate and the superconducting layer, thereby preventing reaction between these layers while epitaxially transmitting the ordered crystalline structure of the single crystal substrate to the superconducting layer. Some examples of buffer layers include CeO₂, yttria-stabilized zirconia (YSZ), (RE)₂O₃, wherein RE can be any of the metals already defined above (e.g., Y₂O₃), LaM′O₃, wherein M′ is a transition or main group metal (e.g., LaAlO₃, LaGaO₃, LaMnO₃, LaCrO₃, LaNiO₃), lanthanum zirconate (e.g., La₂Zr₂O₇), SrTiO₃ (and its Nb-doped analog), NdGaO₃, NbTiO₃, MgO, TiN, TiB₂, Pd, Ag, Pt, and Au. Some common RABiTS architectures include, for example, a four-layer architecture, such as CeO₂/YSZ/Y₂O₃/Ni/Ni—W, and a three-layer architecture, such as CeO₂/YSZ/CeO₂/Ni—W.

Another type of biaxially-textured substrate includes the ion-beam-assisted deposition (IBAD) substrate. IBAD processes and resulting substrates are described in, for example, U.S. Pat. Nos. 6,632,539, 6,214,772, 5,650,378, 5,872,080, 5,432,151, 6,361,598, 5,872,080, 6,756,139, 6,884,527, 6,899,928, and 6,921,741, the disclosures of which are incorporated herein by reference in their entireties. Typically, an IBAD substrate is characterized by an MgO layer (i.e., “IBAD-MgO”) biaxially grown using ion assist on an Al₂O₃/Y₂O₃-coated polycrystalline nickel-based alloy (generally, Hastelloy) base substrate. The Hastelloy substrate is typically deposited on a polycrystalline copper layer. The Al₂O₃ layer serves primarily as a barrier to prevent upward diffusion of substrate components (i.e., functions as a diffusion barrier layer) while the Y₂O₃ layer serves as a seed layer for the IBAD-MgO nucleation. Often, a homo-epitaxial MgO (i.e., homo-epi MgO) layer is epitaxially grown on the IBAD-MgO layer to improve the texture of the IBAD-MgO layer. A texture-transferring capping layer, typically a perovskite layer, such as LaMnO₃ (LMO), SrRuO₃, or SrTiO₃ (but, more typically, LMO) is deposited on the homo-epi MgO layer, or directly on the IBAD-MgO layer. The texture-transferring layer functions to transfer the texture of the MgO layer to the superconducting layer, i.e., wherein the superconducting layer is generally deposited on the capping perovskite layer. An exemplary and widely used IBAD architecture is Al₂O₃/Y₂O₃/IBAD-MgO/homo-epi MgO/LMO.

Yet another type of biaxially-textured substrate includes the inclined-substrate deposition (ISD) substrate. In the ISD process, the resulting substrate has rotated cube texture and the rotation can be as high as 40-45°. ISD processes and resulting substrates are described in, for example, U.S. Pat. Nos. 6,190,752 and 6,265,353, the disclosures of which are incorporated herein by reference in their entireties. In both the IBAD and ISD processes, a biaxially-textured layer is deposited on a flexible, polycrystalline, untextured substrate.

The flux-pinned superconducting films described herein are particularly applied as improved superconducting tapes or wires. As generally understood in the art, a tape or wire generally refers to an article having a width dimension much smaller than its length dimension. The tape or wire can have a length of, for example, at least 0.1 meters (0.1 m), 0.5 m, 1 m, 5 m, 10 m, 50 m, 100 m, 1 km, or more.

A superconducting tape produced by the method described herein can be used in place of any traditional wiring. In particular embodiments, the superconducting tape is used in, for example, a fault current limiter, power transmission cable, electromagnet coil (i.e., superconducting magnet), motor, turbine, transformer, pump, compressor, communication device (e.g., radiofrequency device), wireless device, engine (e.g., in motor vehicle), power storage device, or electrical generator.

Examples have been set forth below for the purpose of illustration and to describe the best mode of the invention at the present time. However, the scope of this invention is not to be in any way limited by the examples set forth herein:

### Example 1

The YBCO films with Ba₂RENbO₆ nanocolumns (RE: rare earth elements including Y) were epitaxially grown by pulsed laser deposition (PLD) using a KrF (λ=248 nm) excimer laser. The PLD targets (2 inch diameter, 0.25 inch thick) were made by mixing YBCO powder and Ba₂RENbO₆ powders using standard ball mixer, followed by densification at 950° C. for 2 h. Ba₂RENbO₆ powders were synthesized by using commercially available powders of RE₂O₃, BaCO₃, and Nb₂O₅ with purities over 99.9% via solid state synthesis process. Laser energy density, repetition rate, and substrate to target distance were 2 J/cm², 10 Hz and 5 cm, respectively. The film growth temperature, Tₛ was 790° C. and the oxygen partial pressure, P(O₂), was 230 mTorr. All depositions were performed on IBAD-MgO templates. The deposition rate of 40 nm/min was obtained during the film growth After deposition, samples were in-situ annealed at Tₛ=500° C. and P(O₂)=500 Torr, and ex-situ annealed at 500° C. for 1 h in flowing O₂ gas after depositing sputtered Ag electrodes onto the films. The standard four-point probe method was used for the transport measurements including superconducting transition temperature, T_{c} and critical current density, J_{c}, with a voltage criterion of 1 μV/cm.

Nb addition into YBCO films was found to result in formation of self-assembled BYNO nanocolumns within YBCO matrix. The volume fraction (%) of BYNO nanophase in Nb-doped samples increases with the addition of Nb as determined by detailed X-ray diffraction analysis and summarized in Table I.

TABLE I
XRD volume fraction (%) of BYNO nanophase and film thickness
for Nb-doped YBCO films.

| | Volume Fraction of BYNO | |
|---|---|---|
| Nb Foil Width | Nanophase | Film Thickness |
| (mm) | (%) | (nm) |
| — | 0 | ~800 |
| 4 | 0.3 | ~800 |
| 10 | 1.3 | ~650 |
| 20 | 5.1 | ~500 |

The Nb doping level was controlled by varying the width of Nb foil attached on the YBCO target. Since laser ablation of the Nb foil produces a plume much smaller than that obtained from the YBCO target, the growth rate and consequently, the film thickness are proportionally reduced by increasing the Nb ablation area with respect to the total ablation area, for the same deposition time. Thicknesses of Nb-doped films with different volume fraction of BYNO nanocolumns were estimated via cross sectional TEM examination, as also summarized in Table I.

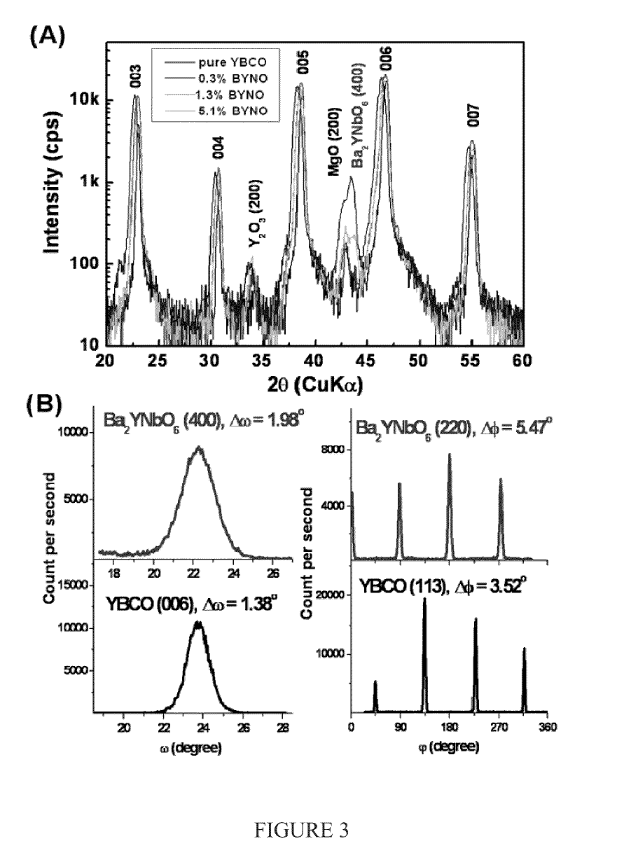

FIG. 3 shows X-ray diffraction results for YBCO films containing Ba₂YNbO₆ nanophase. FIG. 3(A) shows θ-2θ scans for YBCO films with different % volume fractions of Ba₂YNbO₆ nanophase from 0 to 5.1%. FIG. 3(B) omega (ω) and phi (φ) scans of YBCO and Ba₂YNbO₆ phases taken from 5.1% Ba₂YNbO₆ doped YBCO film. FIG. 3 (A) shows that all samples exhibit a sharp out-of-plane c-axis orientation with strong (001) peak intensities of the YBCO phase. For YBCO+BYNO films, there is an additional peak at about 43.5° corresponding to BYNO (400) that provides direct evidence for the formation of an oriented BYNO nanophase within YBCO film. This peak also gets stronger with increasing BYNO volume fraction from 0.3 to 5.1%. Since Nb was only doped into YBCO film during the film growth, the BYNO nanophase is formed by the reaction between YBCO and Nb as represented as

YBa₂Cu₃O_{7-δ}+xNbO_{y}→(1−x)YBa₂Cu₃O_{7-δ}+xBa₂YNbO₆+3xCuO

Excess CuO phase forms in this reaction. However, CuO phase was not detected from θ-2θ scans for YBCO+BYNO films. Plan-view SEM examination shows 100-200 nm sized particles on the surface of YBCO+BYNO samples, which were not observed in pure YBCO film and likely correspond to this excess CuO. Some of the excess CuO is also expected to have been incorporated as 124-type stacking faults within YBCO. The ω- and φ-scans of the YBCO and BYNO phases in the YBCO+5.1% BYNO film shown in FIG. 3(B) show small values of full width half maximum (FWHM) of φ and ω scans (Δφ₍₁₁₃₎˜3.52° and Δω₍₀₀₆₎˜1.38° for the YBCO phase indicating excellent cube-on-cube epitaxy of the YBCO film. Although the BYNO nanophase (Δφ₍₂₂₀₎˜5.47° and Δω₍₄₀₀₎))˜1.98° has larger Δω and Δω than the YBCO film, X-ray results clearly indicate the epitaxial nature of the BYNO nanocolumns within the YBCO film with a crystallographic relationship corresponding to [001]_{BYNO}∥[001]_{YBCO}.

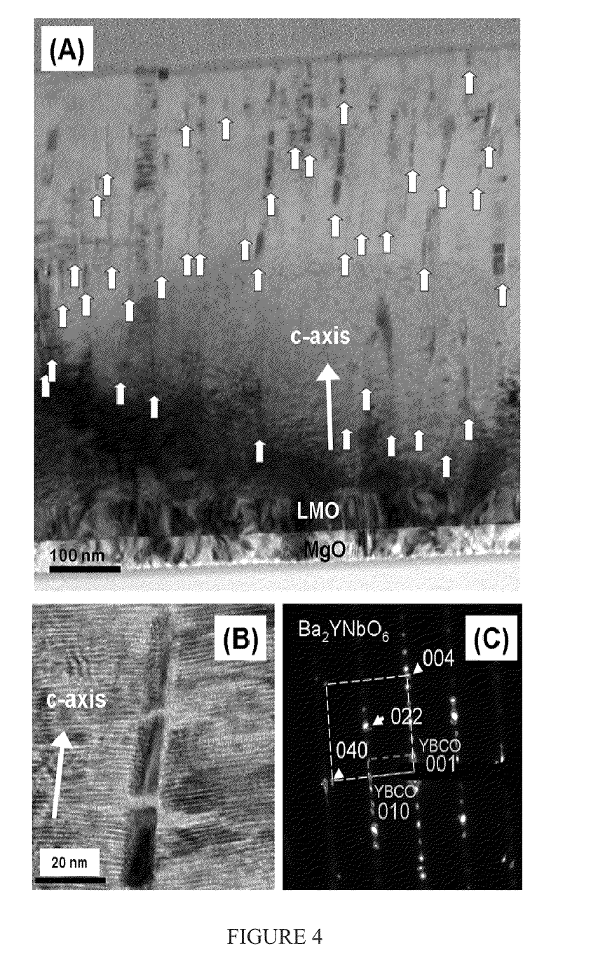

FIG. 4 Transmission electron micrographs of ˜0.5-μm-thick YBCO film with 5.1% Ba₂YNbO₆ nanophase on IBAD-MgO templates. FIG. 4(A) shows cross-sectional TEM image showing the presence of columnar defects comprised of self-assembled Ba₂YNbO₆ nanodots in general along the c-axis as indicated by arrows. FIG. 4(B) shows a higher magnification image of Ba₂YNbO₆ column comprised of a stack of nanorods. FIG. 4(C) shows selected area diffraction (SAD) patterns taken from a cross-section TEM specimen indicating the presence of cubic, double perovskite Ba₂YNbO₆ nanocolumns. These figures show that for a YBCO film containing 5.1% BYNO as shown in FIG. 4(A), BYNO nanocolumns are formed through the entire film thickness and are primarily oriented along the c-axis of YBCO. The density of BYNO nanocolumns is estimated to approximately 500-1000 μm⁻², which corresponds to matching field, B_{φ}, of 1-2 T. Despite the higher volume fraction of the BYNO nanophase in the YBCO matrix, this sample shows areal density and matching fields similar to those of YBCO films containing 1-2 vol % BZO. This can be attributed to the nature of BYNO nanocolumns having nanorods with larger diameters and longer lengths, compared to BZO nanocolumns. Detailed morphological features of individual BYNO nanocolumns are shown in FIG. 4(B). The nanocolumn is composed of a stack of nanorods about 20 nm in length and 7-10 nm in diameter and has a very small gap of about 2-3 nm between the rods. Such morphology is in contrast to that observed in BZO nanocolumns comprised of nanodots in smaller diameters and shorter lengths. FIG. 4(C) shows a selected area diffraction (SAD) pattern for the sample. Diffraction spots caused by the BYNO cubic perovskite structure are observed to be clearly distinguishable from those of the YBCO structure.

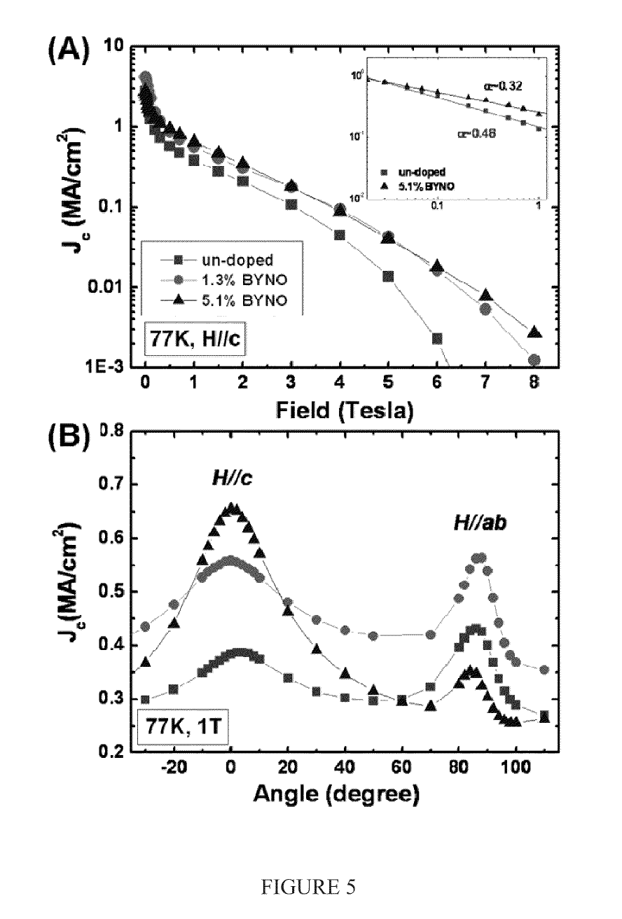

FIG. 5 shows the field dependent J_{c} at 77 K, H∥c with FIG. 5(A) showing the magnetic field up to 8 T and FIG. 5(B) showing the angular dependent J_{c} at 77 K, 1 T for un-doped films, 1.3% doped YBCO films, and 5.1% doped YBCO films. The data shows that YBCO+BYNO films exhibit excellent superconducting properties. The samples with BYNO volume fraction from 0.3 to 5.1% have Tc of 87.4-88.3K which is essentially unchanged compared to the undoped sample with a To of 87.6 K. The film with 1.3% BYNO nanocolumns was measured to have a self-field Jc of 4.1 MA/cm² at 77 K, significantly larger than the Jc of 2.8 MA/cm² for pure YBCO. As shown in FIG. 5, field and angular Jc performance is also improved via incorporation of BYNO nanocolumns. Field dependent Jc for H∥c in FIG. 5 (A) shows that the 1.3 and 5.1% BYNO doped samples have 1.5-7 fold higher Jc in entire magnetic field regime up to 8 T (the highest field at which measurements were made), compared to the pure YBCO film. As shown in the inset of FIG. 5(A), α, the exponent in the power-law of Jc˜H^{-α}, is also greatly reduced from ˜0.48 for undoped sample to ˜0.32 for 5.1% BYNO-doped film, indicating c-axis correlated pinning by BYNO columns. The irreversibility field, Hirr, at 77K is also increased from ˜6:3 T (undoped) to ˜8 T (1.3% BYNO) and over 8 T for the 5.1% BYNO-doped film. FIG. 5(B) shows the angular dependence of Jc at 77 K, 1 T. Compared to the undoped sample, the 1.3% BYNO-doped sample has a higher overall Jc in entire angular range. For the 5.1% BYNO-doped sample, much higher Jc and a stronger peak of Jc at H∥c is observed. However, the Jc appears to be suppressed for the magnetic field orientation away from the c-axis toward the ab-planes. Such an angular Jc behavior is attributed to the increased density of BYNO nanocolumns which sufficiently perturbs the intrinsic pinning from the ab-planes, while strongly enhancing the c-axis correlated pinning. Such effects have been also reported from REBCO films containing a high density of BZO nanocolumns.

### Example-2(Prophetic)

Superconducting films can be fabricated using chemical solution deposition (CSD) on biaxially textured substrates. The chemical precursor solution is coated onto the substrate at room temperature using slot-die coating and/or dip-coating. The coated substrates are heated in a furnace at a first lower temperature for precursor decomposition and then at a higher temperature in the range of 700-900° C. and preferable in the range of 775-850° C. for formation of REBCO. As formed, the films would be epitaxial on the substrate and phase separated into REBCO+double perovskite B(RE,Y)NO phase with B(RE,Y)NO in the form of nanoparticles. The resulting films can then be cooled and annealed in an oxygen atmosphere to fully oxygenate the REBCO phase. The films are expected to have excellent superconducting properties especially in applied magnetic fields due to the presence of nanoparticles of the B(RE,Y)NO phase. It is preferable that the CSD process is a metallorganic deposition (MOD) process. It is also preferred that at least the Ba in the chemical precursor solution is a fluorine compound.

It should be understood that the examples and embodiments described herein are for illustrative purposes only and that various modifications or changes in light thereof will be suggested to persons skilled in the art and are to be included within the spirit and purview of this application. The invention can take other specific forms without departing from the spirit or essential attributes thereof.

We claim:

1. An article comprising a substrate having a biaxially textured surface, and an epitaxial biaxially textured superconducting film supported by said substrate, said epitaxial superconducting film comprising nanoparticles of double perovskite, Ba₂RENbO₆ and being characterized by a critical current density higher than 1 MA/cm² at 77K, self-field.

2. An article in accordance with claim 1, wherein said substrate is selected from the group comprising of a single-crystal substrate, a RABiTS substrate, and an IBAD substrate.

3. An article in accordance with claim 1, wherein said particles of Ba₂RENbO₆ are in the form of aligned columns, aligned within 20 degrees from the c-axis of the superconducting film.

4. An article in accordance with claim 3, wherein said columns are comprised of particles.

5. An article in accordance with claim 3, wherein the columns are comprised of nanorods.

6. An article in accordance with claim 1, wherein said superconducting film characterized by an I_{c} greater than 300 A/cm at 65K, 3 T.

7. A method of making a superconducting article comprising a biaxially textured superconducting material and characterized by a critical current density higher than 1 MA/cm² at 77K, self-field, said method comprising the steps of (a) providing a buffered biaxially textured or single crystal substrate and (b) performing simultaneous deposition of the biaxially textured superconducting material and nanoparticles of double perovskite Ba₂RENbO₆.

8. The method of claim 7, wherein said deposition step comprises an in-situ deposition process selected from the group consisting of pulsed laser ablation, chemical vapor deposition (CVD), metal organic chemical vapor deposition (MOCVD), sputtering and e-beam co-evaporation.

9. The method of claim 7, wherein said deposition step comprises an ex-situ deposition process selected from the group consisting of chemical solution processes, and an ex-situ BaF₂ process, followed by a heat treatment.

10. The method of claim 9, wherein the chemical solution process is selected from the group consisting of TFA-MOD, non-fluorine MOD processes, and reduced fluorine MOD processes.

11. A method of making a superconducting film comprising a biaxially textured superconducting material and characterized by a critical current density higher than 1 MA/cm² at 77K, self-field, said method comprising the steps of:
(a) providing a buffered biaxially textured or single crystal substrate (b) heating the substrate to a preselected deposition temperature under a preselected gas atmosphere and pressure (c) performing simultaneous deposition of the biaxially textured superconducting material and nanoparticles of double perovskite Ba₂RENbO₆.

12. A method in accordance with claim 13 wherein the simultaneous deposition is done using an in-situ deposition process selected from the group consisting of pulsed laser ablation, chemical vapor deposition (CVD), metal organic chemical vapor deposition (MOCVD), sputtering and e-beam co-evaporation.

13. A method in accordance with claim 12 wherein the simultaneous deposition is done using an ex-situ deposition process selected from the group consisting of chemical solution processes, and an ex-situ BaF₂ process, followed by a heat treatment.

14. The method of claim 13, wherein the chemical solution process is selected from the group consisting of TFA-MOD, non-fluorine MOD processes, and reduced fluorine MOD processes.

15. A superconducting article comprising a biaxially textured superconducting composition containing RE, Ba, Cu and O and nanoparticles of double perovskite, Ba₂(Y,RE)NbO₆ and being characterized by a critical current density higher than 1 MA/cm² at 77K, self-field.

16. The superconducting article of claim 15, wherein the superconducting composition comprises REBCO.

17. An article in accordance with claim 15, wherein said particles of Ba₂RENbO₆ are in the form of aligned columns, aligned within 20 degrees from the c-axis of the superconducting film.

18. An article in accordance with claim 15, wherein said columns are comprised of particles.

19. An article in accordance with claim 15, wherein the columns are comprised of nanorods.

20. An article in accordance with claim 15, wherein said superconducting film is characterized by an greater than 300 A/cm at 65K, 3 T.
